(19) United States
(12) Patent Application Publication
(10) Pub. No.: US 2006/0062978 A1
(43) Pub. Date: Mar. 23, 2006

(54) Film forming method, electronic device and electronic apparatus

(76) Inventors: Shinichi Yotsuya, Chino (JP); Tsuyoshi Yoda, Matsumoto (JP); Suguru Akagawa, Suwa (JP)

Correspondence Address: HARNESS, DICKEY & PIERCE, P.L.C., P.O. BOX 828, BLOOMFIELD HILLS, MI, 48303, US

(21) Appl. No.: 11/201,467

(22) Filed: Aug. 11, 2005

(30) Foreign Application Priority Data
Sep. 17, 2004 (JP) 2004-270891

(51) Int. Cl. B32B 15/00; B32B 3/00; B32B 15/20

(52) U.S. Cl. 428/209; 427/248.1; 427/443.1; 428/671

(57) ABSTRACT

A film forming method for forming a thin film pattern on a substrate, comprising a) forming the pattern of a metal base layer on the substrate by vapor-phase deposition with a mask; and b) forming a second metal film on the pattern of the metal base layer by plating the substrate.

### RELATED APPLICATIONS

This application claims priority to Japanese Patent Application No. 2004-270891 filed Sep. 17, 2004 which is hereby expressly incorporated by reference herein in its entirety.

### BACKGROUND

1. Technical Field

The present invention relates to a mask for forming wiring patterns on a substrate by a vapor-phase deposition method and the like.

2. Related Art

Photolithography, dry etching and wet etching have been conventionally used for forming electric wiring on a substrate. These processes, however, need highly expensive facilities which increase product costs due to management expenses for plural processes and yield effects. Further, these processes consume a large amount of resist, development liquid, liquid for removing resist, and liquid or gas for etching. Hence, as shown in Japanese Unexamined Published Patent 4-236758, it is suggested to form a given wiring pattern on a substrate by forming a film with vapor-phase deposition in which a masked pattern with a silicon wafer or a metal thin film is fixed to a substrate. This technique is very effective for manufacturing an organic electro luminescent element, in which materials that are easily deteriorated by humidity and oxygen are heavily used.

However, in order to carry a heavy amount of current, the thickness of a precious metal film such as gold or platinum needs to be thicker when an electrical wiring having low conductivity is formed. Unfortunately, it takes a long time to complete a process with vapor-phase deposition. This lowers product efficiency. Further, this process increases the amount of a precious metal attached to a mask and a manufacturing facility thereby increasing the consumption of precious metals and production cost.

### SUMMARY

To solve the above issue, the present invention aims to provide a film forming method which can form a low conductive electrical wiring with high manufacturing capacity and reduced consumption of precious metals.

According to the first aspect of the invention, a film forming method for forming a thin film pattern on a substrate comprises: a) forming the pattern of a metal base layer on the substrate by vapor-phase deposition with a mask; and b) forming a second metal film on the pattern of the metal base layer by plating the substrate. The invention forms a metal film on the metal base layer by plating thereby avoiding unnecessary metal film and waste of metal material. Therefore, it is easy to form a metal film having a desired thickness.

Further, when the metal base layer is made of gold or nickel, it is sufficient to only form a thin film without removing a surface oxide film. This can shorten processing time and lower the manufacturing cost. Further, when the plating is electroless gold metal plating, a metal film having a desired thickness is favorably formed on the metal base layer made of gold or nickel.

Further, a metal base layer made of aluminum can contribute to lowering costs and is relatively easy to form. Further, when zincate processing is implemented before step (b), an oxide film or a passive film can be removed and replaced with zinc. Further, if a defect portion of the pattern is removed by zincate processing, the defect portion may be easily removed by the etching function of the zincate processing because of the thin thickness even if the defect portion of the metal base layer runs out of the opening of a mask. In particular, even when a desired pattern is not obtained due to contacting a defect portion-which runs out of the opening of a mask, with an adjacent metal base layer, a desired pattern of the metal base layer is obtained.

In the process (b), after electroless plating, substitutive gold plating or electroless gold plating can favorably form a metal film on the metal base layer made of aluminum.

Further, the mask may include an opening portion and a beam connecting one region of the mask separated from a second region of the mask by the opening. This structure forms a first region, a second region separated from the first region by the opening but connected thereto by the beam. The beam enables formation of a complicated opening. As such, it is possible to form a closed pattern wiring with the opening. That is, the beam makes it is possible to continuously form of a thin film pattern on a substrate. Further, thinning the mask plate relative to the thickness of the pattern opening (to form the beam) can fix particles for forming a thin film that are incident from an oblique direction and can form a mask with a miniaturized pattern opening around the beam.

Further, the thickness of the beam may be thinner than the remainder of the mask. This can fix particles for forming a thin film that are incident from a direction other than an oblique direction relative to the substrate.

Further, the mask may be made of silicon. This can reliably form the pattern opening including the beam.

Further, the mask is repeatedly used by removing a thin film formed on the mask, making it possible to form a thin film with low cost.

In the second aspect of the invention, an electronic device includes a metal wiring pattern formed by the film forming method of the first aspect of the invention. This second aspect can provide a low cost metal wire which can carry a massive amount of current thereby attaining a more reliable electronic device with low cost.

The third aspect of the invention is to provide an electronic instrument having the electronic device of the second aspect of the invention. This third aspect of the invention can provide a highly reliable electronic instrument.

### BRIEF DESCRIPTION OF THE DRAWINGS

The invention will be described with reference to the accompanying drawings, wherein like numbers refer to like elements, and wherein:

FIG. 1 is a perspective view including a partial cross-section of the mask 10;

FIGS. 2A to 2C are sequential steps of forming a metal wiring 52;

FIG. 3 shows the metal wiring 52;

FIGS. 4A to 4E are sequential steps of forming the metal wiring 52;

FIG. 5 is a cross sectional view of an organic electro luminescent device 100; and

FIG. 6 shows an embodiment of an electronic instrument.

### DETAILED DESCRIPTION

Embodiments of the invention will now be described with reference to the accompanying drawings.

Mask

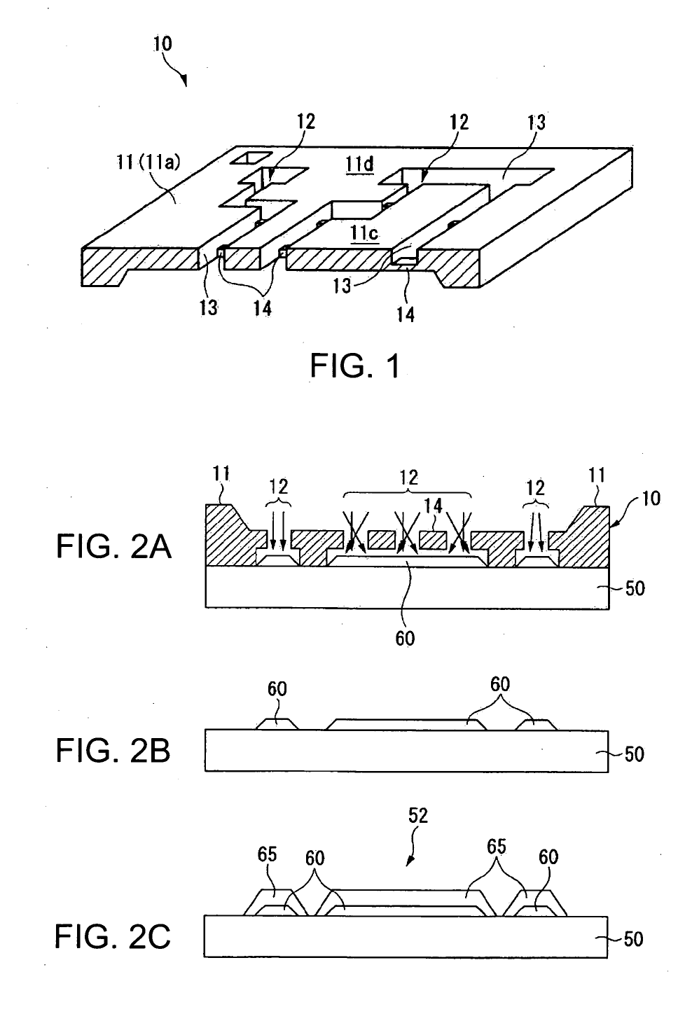

FIG. 1 is a perspective view including a partial cross-section of an example of a mask 10 which is used for forming a thin film pattern on a glass substrate 50 by evaporation, sputtering, and CVD.

The mask 10 includes a plurality of pattern openings 12 formed in a mask base 11 made of silicon. The pattern openings 12 have a line configuration with a width of around 10 μm for example. A metal material is deposited on a substrate via the pattern openings 12 so as to form the electrical wiring pattern having a width of around 10 μm.

The configuration of the pattern openings 12 is not limited to a line, and may include other configurations such as a circle or a rectangle.

Beams 14 are formed within the pattern openings 12 to connect the sidewalls 13 of the pattern opening 12 together. The beams 14 are located at a position spaced apart from a surface 11a in the mask base 11 opposing the substrate. The distance from the surface 11a is preferably at least 5 μm. Hence, a plurality of beams 14 are formed between the sidewalls 13 of the pattern opening 12 which makes it possible to from the pattern opening 12 with a closed configuration in the mask base 11. Namely, a floating portion (like an island) is supported by the beams 14, thereby forming the pattern opening 12 with donut shape. In detail, a portion 11c of the mask base 11 in FIG. 1 is connected to a portion lid of the mask base 11 via beams 14. Therefore, the portion 11c constitutes one integrated part of the mask 10 without dropping off from the mask base 11. Here, the number of beams 14 provided can be freely selected depending on their strength.

The location of the beams 14 spaced apart from the surface 11a enables formation of a continuous metal wiring without decoupling when forming the metal wring on the substrate with the mask 10. Namely, locating the beams 14 far away from the surface 11a fixes a material for the metal wiring to the substrate by surrounding the beams 14. A process for forming the metal wiring is described later.

Materials for the mask base 11 include metal, glass and plastic, but a silicon plate (silicon wafer) is preferred. The beams 14 are easily formed by using these materials. Further, one of these materials may be preferred for a mask for plasma CVD since they are not magnetized. The configuration of the mask base 11 is arbitrary, but its thickness is preferably several hundreds microns.

### First Embodiment

### A Film Forming Method

Next, a method of forming a pattern of the metal wiring 52 on a glass substrate 50 by using the mask 10 is described.

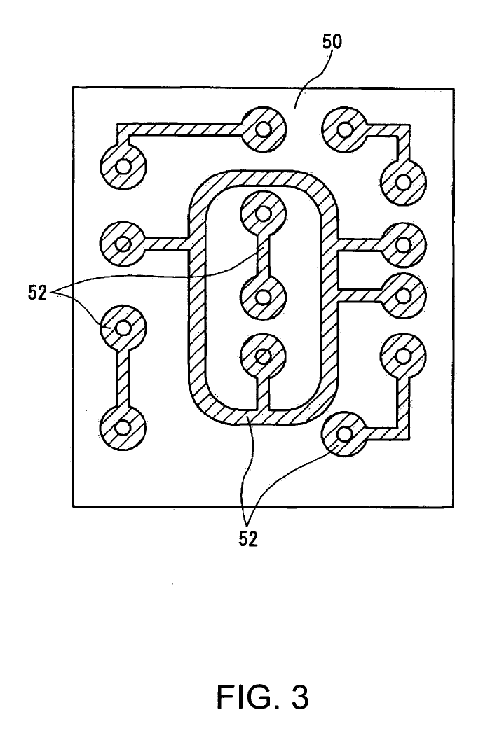

FIG. 2 shows a process for forming the electrical wiring 52 by using the mask 10. FIG. 3 shows the electrical wiring 52 formed by the process.

A substrate for forming the metal wiring 52 is not limited to a glass substrate 10 and other substrates may be used including a plastic substrate or a silicon substrate.

First, a metal base layer 60 is formed on the substrate 50 using the mask 10 by physical vapor-phase deposition such as evaporation and sputtering or a vapor-phase deposition such as CVD. The material of the metal base layer 60 is preferably gold or nickel. The following example is a case when nickel is used.

In detail, as shown in FIG. 2A, the surface 11a of the mask 10 is tightly attached to the glass substrate 50. Then, the metal base layer 60 made of nickel is formed by physical vapor-phase deposition or chemical vapor-phase deposition, as shown in FIG. 2B. The thickness of the metal base layer 60 made of nickel is preferably about 100 nm.

Here, when forming the metal base layer 60, nickel, a material for forming a thin film, passes through the opening 12, reaches the surface of the substrate 50 and deposits thereon. In this case, the material for forming the thin film flows around the beam 14 to reach the entire surface of a region corresponding to the pattern opening 12 on the glass substrate 50 and deposits thereon. Namely, the beam 14 is placed in a position far away from (i.e., spaced apart from) the surface 11a. Therefore, the metal wire 52 may be formed without being interrupted by the existence of the beam 14 and a continuous metal base layer 60 can thereby be provided with no defects (i.e., no disconnections). Therefore, as shown in FIG. 3, the pattern of the metal film, which is a closed configuration, can be favorably formed. This configuration could not be formed by the conventional approach.

Here, it is desirable to space the beams 14 from the surface 11a of the mask 10 by at least 5 μm so that the material for forming the thin film flows around the beams 14, reaches the glass substrate 50 and deposits thereon. If the distance between the beams 14 and the surface 11a of the mask 10 is too close, the amount of material for forming the thin film flowing around the beams 14 is relatively small which makes the thickness of the metal wiring 52 on the glass substrate 50 thin and causes a localized high resistance value thereby prompting disconnection of the wiring.

After forming the metal base layer 60 on the glass substrate 50, the mask 10 is removed from the glass substrate 50 and a nickel thin film deposited on the back surface 11b is removed. In detail, the mask 10 is dipped into hydrochloric acid to remove any attached nickel thin film. Thus, the mask 10 can be repeatedly used which decreases the cost of manufacturing the metal base layer 60.

On the other hand, the glass substrate 50 on which the nickel metal base layer 60 is formed, is dipped into an electroless gold plating liquid. Thus, a gold plated thin film is revealed on the metal base layer 60 to form the metal film 65. The metal film 65 is preferably formed to a thickness of around 2 μm.

An electroless plating method does not need electricity which suppresses production costs. Namely, even if the pattern of the metal film 65 formed on the glass substrate 50 is complicated, there is no need to supply electricity to form all the patterns. This makes the process relatively easy. Further, a plated film having a uniform thickness can be formed on an uneven surface. Such a film can be plated on a non-conductive film such as plastic or ceramic, or a non-iron metal such as aluminum. Further, the manufacturing cost is less than a dry forming method.

By this process, a thick metal film 65 may be easily formed. Namely, the metal deposition continuously progresses by a self-catalytic effect to easily grow a thick gold metal film. Further, gold can be selectively deposited only on the metal base layer 60 to minimize wasting a precious metal. Further, the process is faster than substitute plating which reduces production time.

Here, cyano-gold kalium 2.0 g/l, hypophosphorous acid sodium 10 g/l, ammonium chloride 75 g/l, and sodium acid citrate 50 g/l are mixed as an electroless plating liquid. Then, the PH of the liquid is arranged to five to six with a diluted hydrochloric acid and its temperature is controlled to 90±3° C.

Accordingly, the base metal 60 is formed on the glass substrate by using the mask and then electroless plating is performed to the glass substrate 50 to form the metal film 65 on the metal base layer 60. This process can form a thick metal film 65 to yield a low resistive metal wiring 52 while reducing the amount of precious metal required.

More specifically, when nickel or gold is used, a process of removing an oxide film is not needed since such an oxide film is not formed on the surface of the metal base layer 60. Further, the thickness of the metal base layer 60 can be minimized to reduce the amount of precious metal used since there is no need to remove an oxide film.

Therefore, the metal film 65 made of gold has superiority in electrical conductivity, low contact resistance, corrosion resistance, applicability of solder, abrasion resistance, and may be used not only for the metal wiring 52, but also for various connections, terminals, connectors, lead switches and lead frames.

### Second Embodiment

### A Film Forming Method

Next, a case of using aluminum as a metal base layer 70 is explained in a method of forming a pattern of a metal wiring 54 on the glass substrate 50 by using the mask 10.

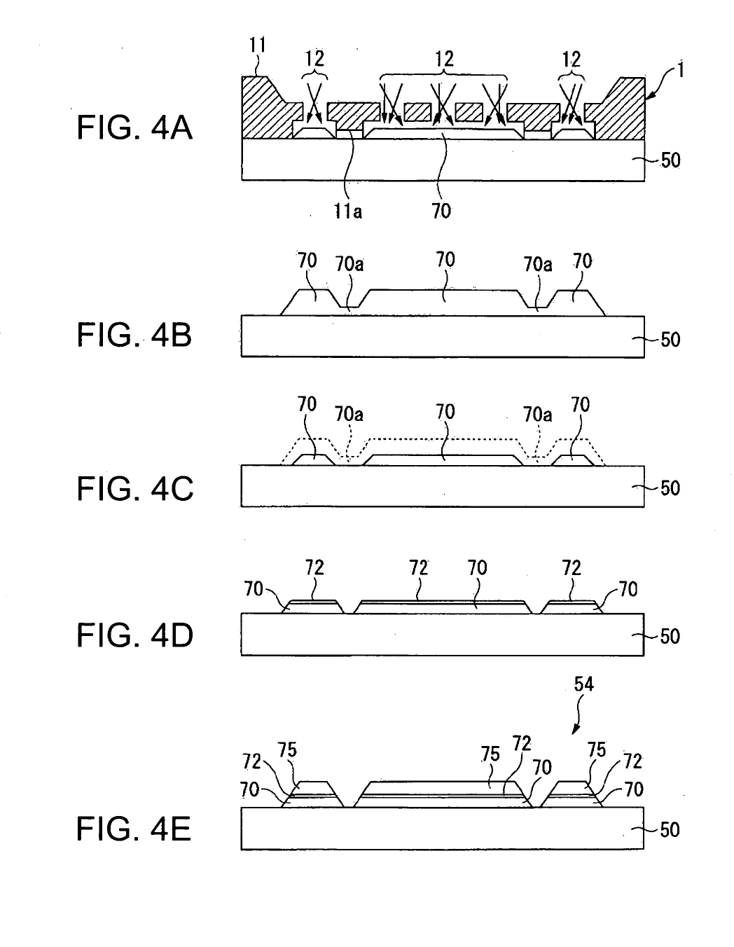

FIGS. 4A to 4E are sequential steps of forming the metal wiring 54.

As shown in FIG. 4A, when aluminum film is formed as the metal base layer 70, the metal base layer 70 is formed on the glass substrate 50 with the mask 10 by an evaporation method, a physical vapor-phase growth method such as sputtering and a physical chemical vapor-phase growth method such as CVD. The thickness of the metal base layer 70 made of aluminum is preferably about 700 nm. Here, in order to form the metal film 70 made of aluminum, an oxide film formed on the surface must be removed to yield the metal film 70 made of aluminum having a thickness of around 100 nm, which is thicker than the metal film made of nickel.

The material for forming the metal base layer 70 may be an aluminum alloy. For example, the alloy may be an alloy of aluminum, silicon and copper.

After forming the metal base layer 70 on the glass substrate 50, the mask 10 is removed from the glass substrate 50 and an aluminum thin film deposited on the back surface 11b is detached. The details of this process are the same as described above.

On the other hand, as shown in FIG. 4B, the glass substrate 50, on which the aluminum base metal film 70 is formed, is flushed with UV in order to remove an organic material attached to the surface.

Next, as shown in FIG. 4C, zincate processing is performed to the glass substrate 50. Zincate processing removes an oxide film formed on the surface of the metal base layer 70 made of aluminum and enhances the adhesiveness of the metal film 75 to the base metal film 70 by substituting the surface with zinc.

In detail, the glass substrate 50, on which the metal base layer 70 made of aluminum is formed, is dipped into a zincate liquid for about one minute. The oxide film on the surface of the metal base layer 70 is thereby removed. Namely, the etching effect caused by zincate processing removes a little of the entire surface of the metal base layer 70. Here, sodium hydroxide at 3 weight % and zinc oxide at 0.5 weight % are mixed as a zincate liquid for example.

The major function of the zincate processing is to substitute the surface material with zinc as well as remove an oxide film at the surface of the aluminum film. But the following additional effect overcoming the following problem can be expected when zincate processing is performed to the glass substrate 50 on which the metal base layer 70 made of aluminum is formed by using the mask 10.

Namely, when the metal base layer 70 is formed by using the mask 10, a material for forming a thin film may run out of the pattern opening 12 of the mask 10 and form the thin film 70a in an unnecessary region. If the thin film 70a running out of the opening contacts the adjacent pattern of the metal base layer 70, a desired pattern can not be obtained and a pattern with defects (short-circuited) of the metal film 70 is formed instead. On the other hand, if zincate processing is performed to the metal base layer 70 having such a defect, the thin film 70a running out of the opening, namely a defect part, is easily removed.

In other words, the material of the metal base layer 70 runs around a space caused by displacing the mask 10 attached to the glass substrate 50 when forming metal base layer 70. This makes the thin film 70a run out of the metal base layer 70 as shown in FIG. 4B. Therefore, the thickness of the thin film 70a running out of the metal base layer 70 is extremely thin compared to the metal base layer 70 corresponding to a region of the pattern opening 12. Hence, when zincate processing is performed to the thin film 70a, this film is detached with an oxide film at the surface of the metal base layer 70.

Accordingly, performing zincate processing to the glass substrate 50, on which the metal base layer 70 made of aluminum is formed, can easily remove the thin film 70a running out of the metal base layer 70. This processing attains favorable desired patterns of the metal base layer 70 as shown in FIG. 4C.

Next, the glass substrate subjected to zincate processing is cleaned with flowing water for about five minutes and electroless-plated thereafter. Finally, a nickel film 72 is formed on the metal base layer 70 as shown in FIG. 4D. In detail, the substrate is dipped into a nickel-phosphor plating liquid heated to around 80° C. for about four minutes to form the nickel film 72 having a thickness of around 1.6 μm on the metal base substrate 70.

As an electroless nickel liquid, nickel sulfate at 0.15 mol/L, malic acid sodium at 0.2 mol/L, succinic acid sodium at 0.2 mol/L, hypophosphorous acid sodium at 0.15 mol/L, and boracic acid at 0.12 mol/L are mixed and then, the PH of the mixture is arranged to 5.4±0.2 with diluted sulphuric acid at a temperature of 80±1° C.

Next, as shown in FIG. 4E, a gold thin film is formed on the nickel film 72 by a substitutive gold plating method and a desired gold film is formed on the nickel film 72 by an electroless gold plating method.

The reason of this additional electroless gold plating after substitutive gold plating is as follows. If electroless gold plating is directly preformed to the surface of nickel film 72, initial gold deposition is implemented with substitution instead of reduction since the difference of ionization tendency between nickel and gold is large. Then, a gold film deposited with the substitution becomes a film having almost non-adhesiveness with the nickel film 72, yielding a problem such as removal. Further, if a gold film is formed on the nickel film 72 by substitutive gold plating, it is substantially impossible to have a thick film, though a film having high adhesiveness is formed.

Hence, in order to overcome this issue, a thin film is formed once on the nickel film 72 by substitutive gold plating. Then a gold film having a desired thickness is further formed on the nickel film 72 by electroless metal plating thereafter.

In detail, the glass substrate 50 is dipped into a substitutive gold plating liquid heated to around 80° C., forming a gold film having a thickness around 0.1 μm on the nickel film 72. Here, as a substitutive gold plating liquid, sodium gold sulfite at 0.7%, thallium sulfite at 6.5 mg/L, EDTA at 3% and lithium sulfite at 10% are mixed for example.

Further, the glass substrate 50 is dipped into an electroless gold plating liquid heated to around 80° C. for about two hours to form a metal film 75 made of gold having a thickness around 2 μm.

In addition to the electroless gold plating liquid described above, sodium gold sulfite at 0.65%, hydroxylamine at 1.0%, thallium sulfite at 0.5 ppm, EDTA at 9.0% and lithium sulfite at 3% may be mixed and then, the PH of the mixture is arranged to 7.0±0.2 with diluted sulphuric acid.

Hence, performing substitutive gold plating and electroless gold plating can form the metal film 75 made of gold to a desired thickness with high adhesiveness, resulting in the low resistance metal wire 54.

Organic Electro Luminescent Device

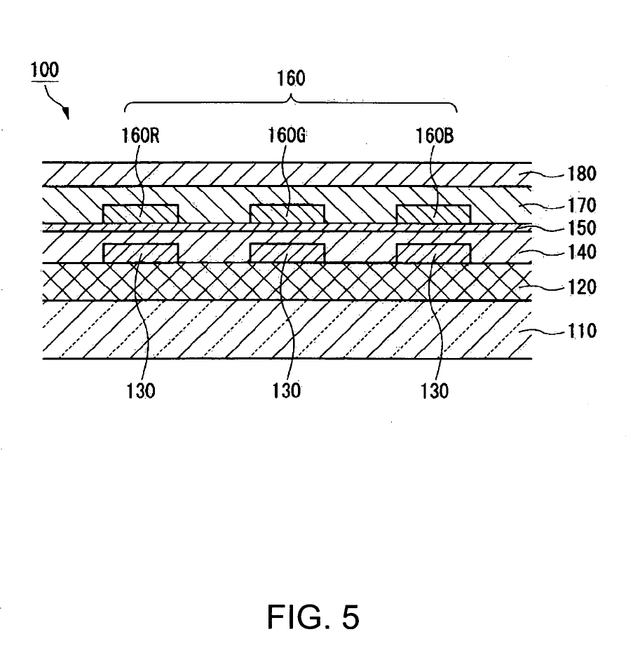

FIG. 5 is a cross sectional view of an organic electro luminescent device 100.

The organic electro luminescent device 100 comprises a plurality of pixel regions arranged in a matrix between a positive electrode 130 and a negative electrode 180. The pixel regions include emission layers 160R, 160G and 160B made of an organic material. A circuit part 120 for driving each pixel region (emission layers 160R, 160G and 160B) is formed on the surface of the substrate 110 made of glass. In FIG. 5 the details of the circuit part 120 are omitted, but the wiring of this circuit 120 is formed by the above mentioned method.

Pixel electrodes 130 made of ITO are formed in a matrix corresponding to each pixel region on the surface of the circuit part 120.

Then, a hole injection layer 140 made of copper phthalocyanine is formed to cover the pixel electrodes 130, which function as positive electrodes. Further, a hole transport layer 150 made of NPB (N,N-di(naphthalene)-N,N-diphenyl benzidene) and the like is formed on the hole injection layer 140.

The emission layers 160R, 160G and 160B corresponding to the pixel regions are formed in a matrix on the surface of the hole transport layer 150. The emission layers 160 are made of a low molecule organic material having a molecular weight under 1000, for example. In detail, the emission layers 160 comprise Alq3 (aluminum complex) as a host, and rubrene as a dopant.

Further, an electron injection layer 170 made of lithium fluoride and the like is formed to cover each of the emission layers 160 and the negative electrode 180 made of aluminum is formed on the surface of the electron injection layer 170. A sealing substrate (not shown) attached to the end part of the substrate 110 seals over the entire device.

When a voltage is applied to the pixel electrode 130 and the negative electrode 180, holes are injected to the emission layers 160 by the hole injection layer 140 and electrons are injected to the emission layers 160 by the electron injection layer 170. Then, holes are recombined with electrons within the emission layer 160 and emit light due to dopant excitation. This is advantageous in that the organic EL device 100 provided with the emission layers 160 made of an organic material has a long life and shows excellent emission efficiency.

Electronic Instrument

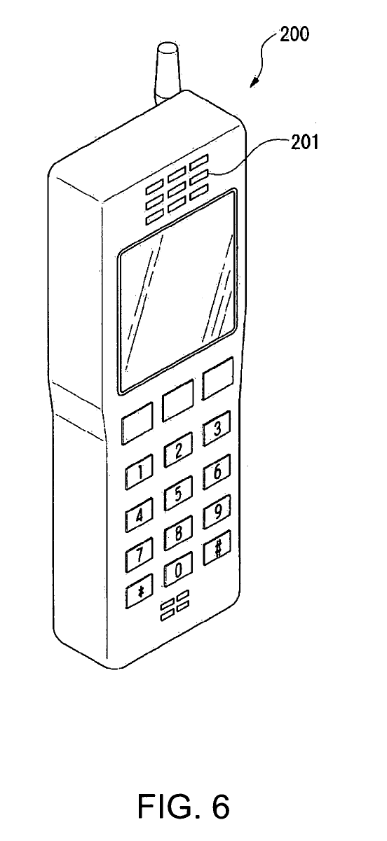

FIG. 6 shows an electronic instrument according to the embodiment of the invention. A mobile phone 200 is provided with a display 201 including the low molecule organic EL device 100. As other applications, the low molecule organic EL device 100 is used as a display for a wrist watch type electronic device, or is used as a display for a mobile type information processing device such as a word processor or a personal computer.

The mobile phone 200 provided with the low molecule organic EL device 100 as the display 201 can realize high quality display with high contrast.

Preferred embodiments of the invention have been explained referring to the drawings, but the invention is not limited to these embodiments. The configurations and combinations of elements described above are merely examples, and can be diversely modified in response to design requests within the spirit and scope of the invention.

As examples of modifications, a material for the metal film 65 and 75 was gold, but is not limited thereto. For example, silver, platinum or palladium may also be used. When electroless-plating with palladium, palladium chloride 0.12 at mol/L, sodium acid citrate at 0.3 mol/L, hypophosphorous acid at 0.05 mol/L, lead nitrate at 100 ppm, boric acid at 0.2 mol/L are mixed as an electroless palladium plating liquid. Then, the PH of the liquid is arranged to 5.4±0.2 with diluted sulphuric acid at a temperature of 80±1° C.

Further, the metal films 65 and 75 were formed by electroless plating, but may be formed by electro plating. This electro plating is appropriate for palladium.

Further, the mask for forming the metal base layers 60 and 70 was made of single crystal silicon, but is not limited thereto. A mask made of stainless steel may be used for example.

What is claimed is:

1. A film forming method for forming a thin film pattern on a substrate, comprising;
a) forming the pattern of a metal base layer on the substrate by vapor-phase deposition with a mask;
b) forming a second metal film on the pattern of the metal base layer by plating the substrate.

2. The film forming method according to claim 1, wherein the metal base layer comprises at least one of gold and nickel.

3. The film forming method according to claim 1, wherein the plating comprises electroless plating.

4. The film forming method according to claim 1, wherein the metal base layer comprises aluminum.

5. The film forming method according to claim 1, further comprising performing zincate processing before step (b).

6. The film forming method according to claim 5, wherein the zincate processing removes a defect from the pattern.

7. The film forming method according to claim 4, wherein step (b) includes at least one of substitutive gold plating and electroless gold plating, after electroless nickel plating.

8. The film forming method according to claim 1, wherein the mask includes an opening portion and a beam connecting a first region of the mask to a second region of the mask separated from the first region by the opening.

9. The film forming method according to claim 1, wherein the beam is thinner than the mask.

10. The film forming method according to claim 8, wherein the mask comprises silicon.

11. The film forming method according to claim 1, wherein the mask a thin film formed on the mask is removed after step b).

12. An electronic device comprising the metal wire pattern formed by the film forming method according to claim 1.

13. The electronic apparatus comprising the electronic device according to claim 12.
